(19) United States
(12) Patent Application Publication
(10) Pub. No.: US 2015/0234228 A1
(43) Pub. Date: Aug. 20, 2015

(54) LIQUID CRYSTAL DISPLAY AND METHOD OF MANUFACTURING THE SAME

(71) Applicant: Samsung Display Co., Ltd., Yongin-City (KR)

(72) Inventors: Ho Yun BYUN, Osan-si (KR); Jae Cheol PARK, Hwaseong-si (KR); Gyeong Eun EOH, Seoul (KR)

(21) Appl. No.: 14/469,443

(22) Filed: Aug. 26, 2014

(30) Foreign Application Priority Data
Feb. 17, 2014 (KR) 10-2014-0018049

(51) Int. Cl. G02F 1/1333; H01L 27/12; G02F 1/1339; G02F 1/1335; G02F 1/1368; G02F 1/1341

(52) U.S. Cl. CPC G02F 1/133377; G02F 1/1368; G02F 1/1341; G02F 1/1339; G02F 1/133528; H01L 27/1259

(57) ABSTRACT

A liquid crystal display is provided. The liquid crystal display according to an exemplary embodiment of the inventive concept includes: a substrate; a thin film transistor disposed on the substrate; a pixel electrode connected to the thin film transistor; a roof layer facing the pixel electrode; an adhesive layer disposed on the roof layer; and a capping layer disposed on the adhesive layer, wherein a plurality of microcavities are formed between the pixel electrode and the roof layer, and the microcavity forms a liquid crystal layer including a liquid crystal material.

### CROSS-REFERENCE TO RELATED APPLICATION

This application claims priority to and the benefit of Korean Patent Application No. 10-2014-0018049 filed in the Korean Intellectual Property Office on Feb. 17, 2014, the entire contents of which are incorporated herein by reference.

### BACKGROUND

(a) Field

The inventive concept relates to a liquid crystal display and a manufacturing method thereof.

(b) Description of the Related Art

A liquid crystal display as one of flat panel display devices that are widely used includes two display panels where field generating electrodes such as pixel electrodes and a common electrode are formed, and a liquid crystal layer interposed therebetween.

The liquid crystal display generates an electric field in the liquid crystal layer by applying voltages to the field generating electrodes, to determine orientations of liquid crystal molecules of the liquid crystal layer and control polarization of incident light, thereby displaying an image.

A technique of implementing a display by forming a plurality of microcavities in a pixel and filling a liquid crystal therein has been developed for one of the liquid crystal displays. Two sheets of substrates are used in a liquid crystal display in the related art, but the technique of forming constituent elements on one substrate may reduce weight, thickness, and the like of the device.

A process of forming the display by filling the liquid crystal in the microcavities includes a process of forming a capping layer after the liquid crystal is injected into the microcavities. To form the capping layer, if a hardening process is performed after coating a liquid phase of the coating material, contamination of the liquid crystal by impurities in the coating material due to the contact between the liquid crystal and the coating material is inevitably occurred and stains due to non-uniform coating of the coating material may be generated.

The above information disclosed in this Background section is only for enhancement of understanding of the background of the inventive concept and therefore it may contain information that does not form the prior art.

### SUMMARY

The inventive concept provides a liquid crystal display in which liquid crystal contamination and stain generation are prevented, and a manufacturing method thereof.

A liquid crystal display according to an exemplary embodiment of the inventive concept includes: a substrate; a thin film transistor disposed on the substrate; a pixel electrode connected to the thin film transistor; a roof layer facing the pixel electrode; an adhesive layer disposed on the roof layer; and a capping layer disposed on the adhesive layer, wherein a plurality of microcavities are formed between the pixel electrode and the roof layer, and each micro-cavity forms a liquid crystal layer including a liquid crystal material.

A liquid crystal injection hole formation region may be formed between a plurality of microcavities, and the liquid crystal material may be disposed at the liquid crystal injection hole formation region.

A lower portion of the capping layer corresponding to the liquid crystal injection hole formation region may be substantially flat.

The adhesive layer may be disposed on the roof layer, and may be removed in the liquid crystal injection hole formation region.

The substrate may further include a sealing member and the sealing member surrounds a display area and is disposed at the peripheral area in which image in not displayed.

A liquid crystal injection hole formation region may be formed between the plurality of microcavities, and the adhesive layer may be disposed at the liquid crystal injection hole formation region.

The adhesive layer may have a characteristic that viscosity is changed according to temperature.

The liquid crystal injection hole formation region may be formed between a plurality of microcavities, the capping layer may be disposed at the liquid crystal injection hole formation region, and the adhesive layer may be disposed on the roof layer and may be removed at the liquid crystal injection hole formation region.

A polarizer disposed on the capping layer may be further included, and an upper surface of the capping layer that is exposed between an end of the polarizer and an end of the capping layer may be flat.

The end of the polarizer and the end of the capping layer may be disposed at the peripheral area of the substrate.

A protection film disposed on the capping layer may be further included.

The liquid crystal injection hole formation region may be formed between a plurality of microcavities, and the adhesive layer may include a hardened adhesion region disposed at a portion corresponding to the liquid crystal injection hole formation region.

A manufacturing method of a liquid crystal display according to an exemplary embodiment of the inventive concept includes: forming a thin film transistor on a substrate; forming a pixel electrode to be connected to one terminal of the thin film transistor; forming a sacrificial layer on the pixel electrode; forming a roof layer on the sacrificial layer; removing the sacrificial layer to form a plurality of microcavities; injecting a liquid crystal material into the microcavities; and attaching a capping layer on the roof layer.

The capping layer may have an adhesive layer on at least one surface and attaching a capping layer on the roof layer is performed by the adhesive.

The method may further include forming a liquid crystal injection hole formation region between a plurality of microcavities, and the injecting of the liquid crystal material may include forming a liquid crystal material at the liquid crystal injection hole formation region.

The capping layer may include a first portion corresponding to the roof layer and a second portion corresponding to the liquid crystal injection hole formation region, and the adhesive layer may be formed at the first portion and may be removed at the second portion in the forming of the adhesive layer.

The method may further include forming a sealing member at the peripheral area in which image in not displayed and the sealing member may surround a display area.

The method may further include forming a liquid crystal injection hole formation region between a plurality of microcavities and removing the liquid crystal material on the liquid crystal injection hole formation region.

The adhesive layer may have a characteristic that viscosity is changed according to temperature, and the forming of the adhesive layer may include heat-treating the adhesive layer to reflow the adhesive layer into the liquid crystal injection hole formation region.

The method may further include forming a sealing member at the peripheral area in which image in not displayed and the sealing member may surround a display area.

The forming of the capping layer may include heat-treating the capping layer to reflow the capping layer into the liquid crystal injection hole formation region.

The method may further include forming a polarizer on the capping layer, and an upper surface of the capping layer exposed between an end of the polarizer and an end of the capping layer may be flat.

The end of the polarizer and the end of the capping layer may be formed to be disposed in the peripheral area of the substrate.

The method may further include forming a protection film on the capping layer.

The method may further include: forming a liquid crystal injection hole formation region between a plurality of microcavities; forming an adhesive layer between the roof layer and the capping layer; and heat-treating or irradiating UV to a portion of the adhesive layer corresponding to the liquid crystal injection hole formation region to form a hardened adhesion region.

According to an exemplary embodiment of the inventive concept, after injecting the liquid crystal to the microcavity, the capping layer is formed by a film lamination process such that liquid crystal contamination caused by conventional liquid coating and stains caused by coating non-uniformity may be prevented.

### BRIEF DESCRIPTION OF THE DRAWINGS

FIG. 1 is a top plan view of a liquid crystal display according to an exemplary embodiment of the inventive concept.

FIG. 2 is a cross-sectional view taken along a line II-II of FIG. 1.

FIG. 3 is a cross-sectional view taken along a line III-III of FIG. 1.

FIG. 4 is a cross-sectional view of a variation of a liquid crystal display according to an exemplary embodiment of FIG. 2.

FIG. 5 is a cross-sectional view of a variation of a liquid crystal display according to an exemplary embodiment of FIG. 2.

FIG. 6 is a cross-sectional view of a variation of a liquid crystal display according to an exemplary embodiment of FIG. 2.

FIG. 7 is a cross-sectional view of a variation of a liquid crystal display according to an exemplary embodiment of FIG. 6.

FIG. 8 and FIG. 9 are cross-sectional views of a liquid crystal display according to an exemplary embodiment of the inventive concept.

FIG. 10 is a top plan view partially showing a peripheral area and a display area in a liquid crystal display according to an exemplary embodiment of the inventive concept.

FIG. 11 is a schematic cross-sectional view of a liquid crystal display according to the exemplary embodiment of FIG. 10 in a view of a side surface.

FIG. 12 is a top plan view partially showing a peripheral area and a display area in a liquid crystal display according to an exemplary embodiment of the inventive concept.

FIG. 13 is a schematic cross-sectional view of a liquid crystal display according to the exemplary embodiment of FIG. 12 in a view of a side surface.

FIG. 14 to FIG. 30 are cross-sectional views showing a manufacturing method of a liquid crystal display according to an exemplary embodiment of the inventive concept.

### DETAILED DESCRIPTION OF THE EMBODIMENTS

The inventive concept will be described more fully hereinafter with reference to the accompanying drawings, in which exemplary embodiments of the inventive concept are shown. As those skilled in the art would realize, the described embodiments may be modified in various different ways, all without departing from the spirit or scope of the inventive concept. Rather, the exemplary embodiments of the inventive concept are provided so that this disclosure will be thorough and complete, and will fully convey the concept of the inventive concept to those skilled in the art.

In the drawings, the thickness of layers and regions may be exaggerated for clarity. In addition, when a layer is described to be formed on another layer or on a substrate, this means that the layer may be formed on the other layer or on the substrate, or a third layer may be interposed between the layer and the other layer or the substrate. Like numbers refer to like elements throughout the specification.

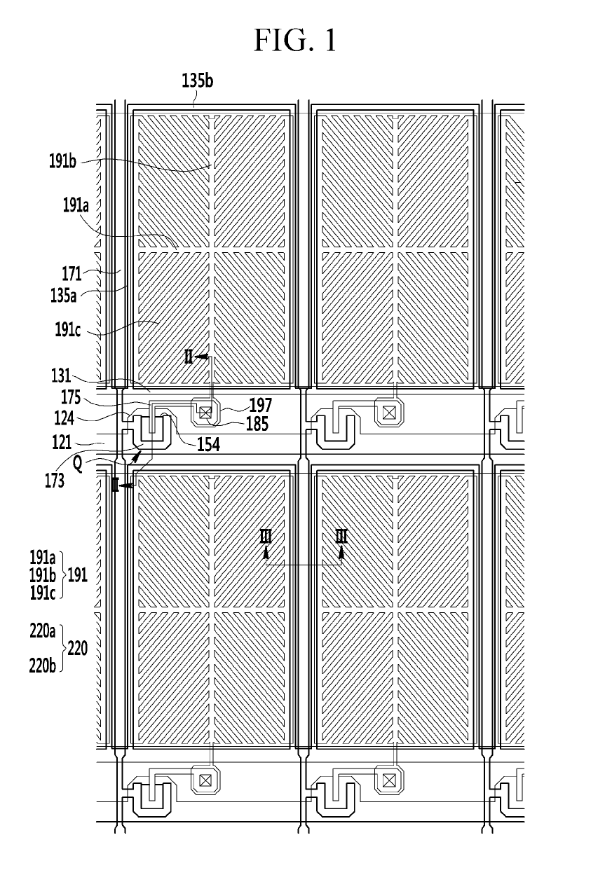

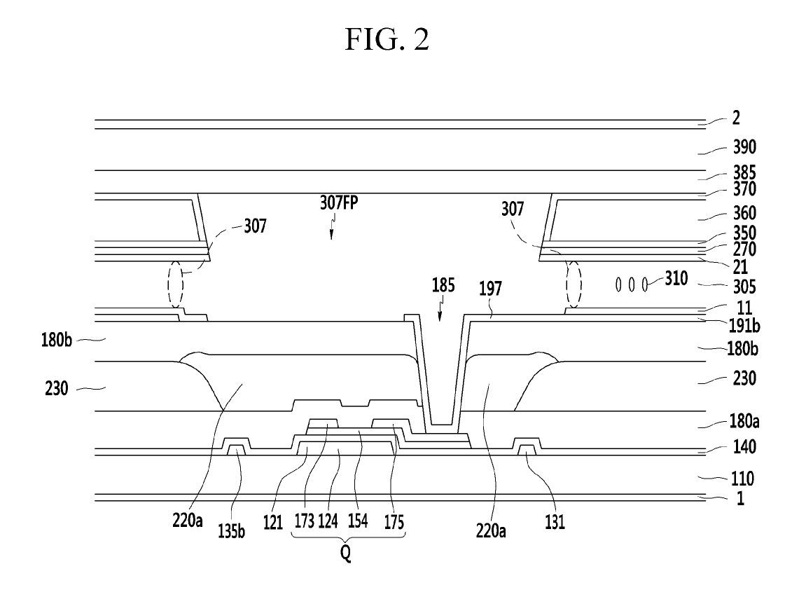

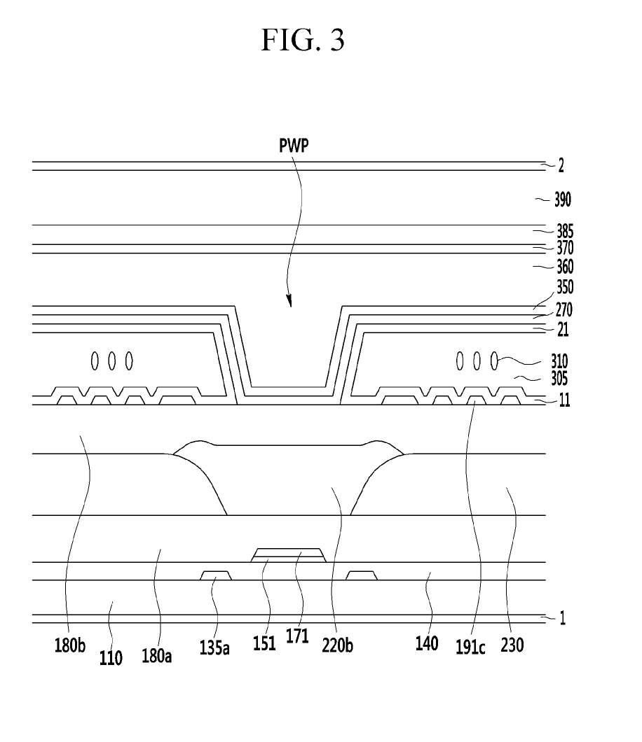

FIG. 1 is a top plan view of a liquid crystal display according to an exemplary embodiment of the inventive concept. FIG. 2 is a cross-sectional view taken along a line II-II of FIG. 1. FIG. 3 is a cross-sectional view taken along a line III-III of FIG. 1.

FIG. 1 shows a 2*2 pixel portion as a center portion of a plurality of pixels, and these pixels may be repeatedly arranged up/ down and right/left in the liquid crystal display according to an exemplary embodiment of the inventive concept.

Referring to FIG. 1 to FIG. 3, a gate line 121 and a storage electrode line 131 are formed on a substrate 110 made of transparent glass or plastic. The gate line 121 includes a gate electrode 124. The storage electrode line 131 mainly extends in a horizontal direction, and transfers a predetermined voltage such as a common voltage Vcom. The storage electrode line 131 includes a pair of vertical storage electrode portions 135a substantially extending to be perpendicular to the gate line 121, and a horizontal storage electrode portion 135b connecting ends of the pair of vertical storage electrode portions 135a to each other. The storage electrode portions 135a and 135b have a structure surrounding a pixel electrode 191.

A gate insulating layer 140 is formed on the gate line 121 and the storage electrode line 131. A semiconductor layer 151 provided at a lower portion of a data line 171, and a semiconductor layer 154 disposed at a lower portion of a source/drain electrode and at a channel portion of a thin film transistor Q is formed on the gate insulating layer 140.

A plurality of ohmic contacts may be formed on each of the semiconductor layers 151 and 154, and between the data line 171 and the source/drain electrode, but this is omitted in the drawings. Data conductors including a source electrode 173, the data line 171 connected with the source electrode 173, and a drain electrode 175 are formed on each of the semiconductor layers 151 and 154 and the gate insulating layer 140.

According to another embodiment of the inventive concept, the semiconductor layer 151 may not be formed at a lower portion of a data line 171.

The gate electrode 124, the source electrode 173, and the drain electrode 175 form the thin film transistor Q together with the semiconductor layer 154, and a channel of the thin film transistor Q is formed on the portion of the semiconductor layer 154 between the source electrode 173 and the drain electrode 175. A first interlayer insulating layer 180a is formed on the data conductors 171, 173, and 175 and an exposed portion of the semiconductor layer 154. The first interlayer insulating layer 180a may include an inorganic insulating material such as a silicon nitride (SiNx) and a silicon oxide (SiOx), or an organic insulating material.

A color filter 230 and a light blocking member 220 are formed on the first interlayer insulating layer 180a.

The light blocking member 220 has a lattice structure having an opening corresponding to a region displaying an image, and is formed of a material that prevents light from being transmitted therethrough. The color filter 230 is formed at an opening of the light blocking member 220. The light blocking member 220 includes a horizontal light blocking member 220a formed in a direction parallel to the gate line 121, and a vertical light blocking member 220b formed in a direction parallel to the data line 171.

The color filter 230 may display one of primary colors, such as three primary colors including red, green, and blue. However, the colors are not limited to the three primary colors including red, green, and blue, and the color filter 230 may also display one among a cyan-based color, a magenta-based color, a yellow-based color, and a white-based color. The color filter 230 may be formed of materials displaying different colors for each adjacent pixel.

A second interlayer insulating layer 180b covering the color filter 230 and the light blocking member 220 is formed on the color filter 230 and the light blocking member 220. The second interlayer insulating layer 180b may include an inorganic insulating material such as a silicon nitride (SiNx) and a silicon oxide (SiOx), or the organic insulating material. Unlike the cross-sectional view of FIG. 2, in a case where a step is generated due to a difference in thickness between the color filter 230 and the light blocking member 220, the second interlayer insulating layer 180b includes an organic insulating material, so that it is possible to decrease or remove the step.

The color filter 230, the light blocking member 220, and the interlayer insulating layer 180a and 180b have a contact hole 185 exposing the drain electrode 175.

A pixel electrode 191 is formed on the second interlayer insulating layer 180b. The pixel electrode 191 may be formed of a transparent conductive material such as ITO or IZO.

An overall shape of the pixel electrode 191 is a quadrangle, and the pixel electrode 191 includes a cross stem having a horizontal stem 191a and a vertical stem 191b crossing the horizontal stem 191a. Further, the pixel electrode 191 is divided into four sub-regions by the horizontal stem 191a and the vertical stem 191b, and each sub-region includes a plurality of minute branches 191c. In the present exemplary embodiment, the pixel electrode 191 may further include an outer stem surrounding an outer circumference of the pixel electrode 191.

The minute branches 191c of the pixel electrode 191 form an angle of approximately 40° to 45° with the gate line 121 or the horizontal stem 191a. Further, the minute branches of two adjacent sub-regions may be perpendicular to each other.

Furthermore, a width of each minute branch may be gradually increased, or a distance between the minute branches 191c may be varied.

The pixel electrode 191 includes an extension 197 which is connected to a lower end of the vertical stem 191b and has a larger area than the vertical stem 191b, and is physically and electrically connected with the drain electrode 175 through the contact hole 185 at the extension 197 to receive a data voltage from the data electrode 175.

The thin film transistor Q and the pixel electrode 191 described above are just described as examples, and a structure of the thin film transistor and a design of the pixel electrode may be modified in order to improve side visibility.

A lower alignment layer 11 is formed on the pixel electrode 191, and may be a vertical alignment layer. The lower alignment layer 11, as a liquid crystal alignment layer made of a material such as polyamic acid, polysiloxane, polyimide, or the like, may include at least one of generally used materials. Also, the lower alignment layer 11 may be a photo-alignment layer.

An upper alignment layer 21 is provided at a portion facing the lower alignment layer 11, and a microcavity 305 is formed between the lower alignment layer 11 and the upper alignment layer 21. A liquid crystal material including liquid crystal molecules 310 is injected into the microcavity 305 through an injection hole 307. In the present exemplary embodiment, the alignment material forming the alignment layers 11 and 21 and the liquid crystal material including the liquid crystal molecules 310 may be injected into the microcavity 305 by capillary force. The lower alignment layer 11 and the upper alignment layer 21 may be formed in a same process and be connected each other as disclosed in FIG. 3.

A plurality of liquid crystal injection hole formation regions 307FP are disposed between adjacent microcavity at a portion overlapping the gate line 121, thereby forming the plurality of microcavities 305, and a plurality of microcavities 305 may be formed along a column direction of the pixel electrode 191, that is, in the vertical direction. Also, the microcavity 305 is divided in the horizontal direction by a partition formation part PWP that will be described later, thereby forming the plurality of microcavities 305, and the plurality of microcavities 305 may be formed along the row direction of the pixel electrode 191, in other words, the horizontal direction in which the gate line 121 extends. Each of the plurality of microcavities 305 may be formed in a region correspond to a pixel area which display one of the primary colors, and the pixel areas may correspond to a region displaying an image. However, two adjacent microcavities arranged along the column direction may correspond to the pixel area.

A common electrode 270 and a lower insulating layer 350 are disposed on the upper alignment layer 21. The common electrode 270 receives the common voltage, and generates an electric field together with the pixel electrode 191 to which the data voltage is applied to determine a direction in which the liquid crystal molecules 310 disposed in the microcavity 305 between the two electrodes are inclined. The common electrode 270 forms a capacitor with the pixel electrode 191 to maintain the received voltage even after the thin film transistor is turned off. The lower insulating layer 350 may be formed of a silicon nitride (SiNx) or a silicon oxide (SiOx).

In the present exemplary embodiment, it is described that the common electrode 270 is formed on the microcavity 305, but in another exemplary embodiment, the common electrode 270 is formed under the microcavity 305, so that liquid crystal driving according to a coplanar electrode (CE) mode is possible.

A roof layer 360 is disposed on the lower insulating layer 350. The roof layer 360 serves to make a support so that the microcavity 305, which is a space between the pixel electrode 191 and the common electrode 270, is maintained. The roof layer 360 may include a photoresist or other organic materials.

An upper insulating layer 370 is disposed on the roof layer 360. The upper insulating layer 370 may contact an upper surface of the roof layer 360. The upper insulating layer 370 may be formed of a silicon nitride (SiNx) or a silicon oxide (SiOx). The upper insulating layer 370 may be omitted.

A capping layer 390 having an adhesive layer 385 on one side is attached to the upper insulating layer 370. The capping layer 390 adheres to the upper insulating layer 370 by an adhesive layer 385, and when the upper insulating layer 370 is omitted, the capping layer 390 adheres to the roof layer 360 by the adhesive layer 385. The capping layer 390 includes an organic material or an inorganic material, and may have a film shape. A lower portion of the capping layer 290 corresponding to the liquid crystal injection hole formation region 307FP may be substantially flat.

In the present exemplary embodiment, the capping layer 390 is not only disposed on the roof layer 360 but also covers the liquid crystal injection hole formation region 307FP.

A lower polarizer 1 is disposed under the substrate 110 and an upper polarizer 2 is disposed on the capping layer 390.

In the present exemplary embodiment, the liquid crystal material may remain at the liquid crystal injection hole formation region 307FP even after the liquid crystal material is injected into the microcavity 305. The liquid crystal material that remains at the liquid crystal injection hole formation region 307FP is covered by the capping layer 390 having the adhesive layer 385.

In the present exemplary embodiment, as shown in FIG. 3, a partition wall PWP is disposed between the microcavities 305 adjacent to each other in a horizontal direction. The partition wall formation portion PWP may be formed in an extending direction of the data line 171, and may be covered by the roof layer 360. The lower insulating layer 350, the common electrode 270, the upper insulating layer 370, and the roof layer 360 are filled in the partition wall formation portion PWP, and the structure forms the partition wall to partition or define the microcavity 305. In the present exemplary embodiment, since a partition wall structure such as the partition wall formation portion PWP exists between the microcavities 305, even if the insulation substrate 110 is bent, generated stress is small, and a change in a cell gap may be considerably reduced.

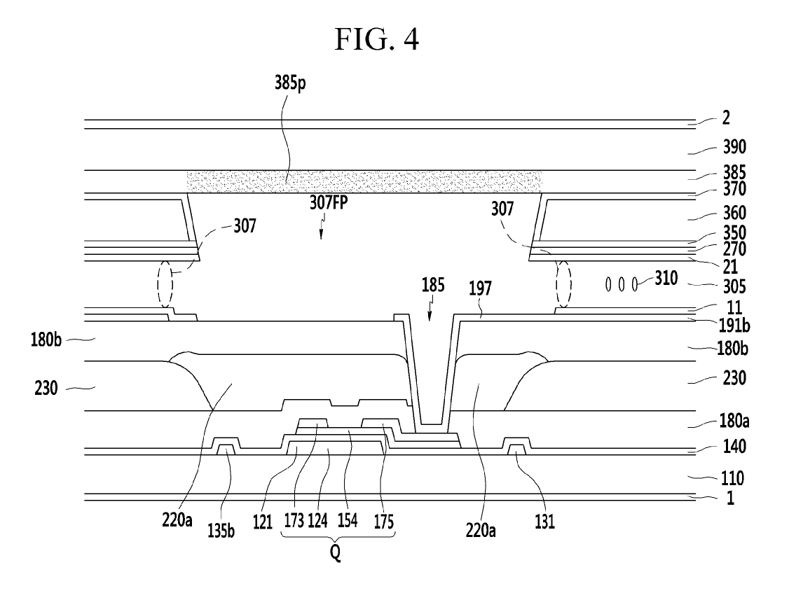

FIG. 4 is a cross-sectional view of a variation of a liquid crystal display according to an exemplary embodiment of FIG. 2.

The exemplary embodiment described in FIG. 4 is almost the same as the exemplary embodiment described in FIG. 1 to FIG. 3. Hereafter, a difference between the present exemplary embodiment and the exemplary embodiment of FIG. 1 to FIG. 3 will be described.

Referring to FIG. 4, the adhesive layer 385 in an adhesion region 385p that is disposed at a portion corresponding to the liquid crystal injection hole formation region 307FP is hardened. The hardened adhesion region 385p may be formed by irradiating UV or applying heat treatment to the adhesive layer 385. When irradiating UV, a shadow mask may cover a portion except for the portion corresponding to the liquid crystal injection hole formation region 307FP. In the present exemplary embodiment, the hardened adhesion region 385p has decreased reactivity with the liquid crystal material such that the liquid crystal material that remains in the liquid crystal injection hole formation region 307FP would not react with the adhesive layer 385, thereby preventing contamination of the liquid crystal.

Except for the described differences, the contents described in FIG. 1 to FIG. 3 may all be applied to the present exemplary embodiment.

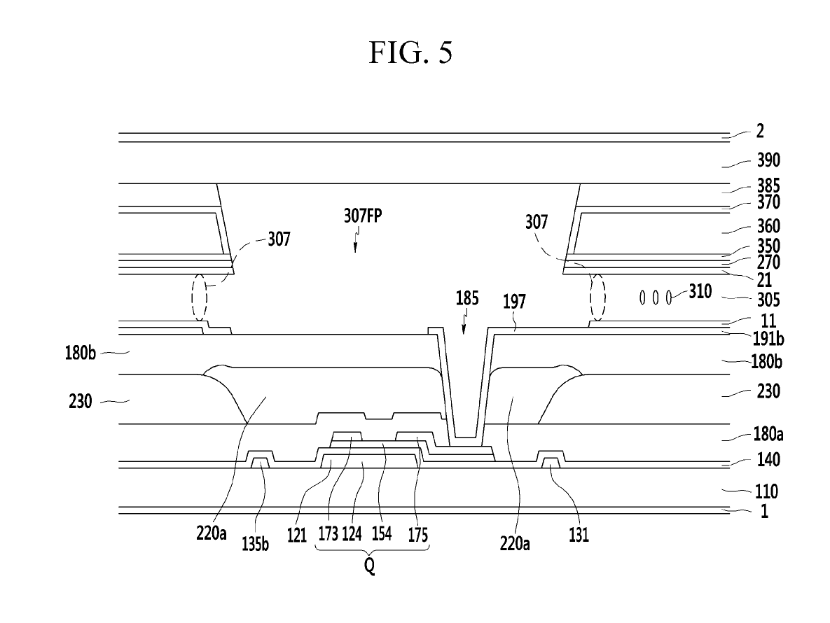

FIG. 5 is a cross-sectional view of a variation of a liquid crystal display according to an exemplary embodiment of FIG. 2.

The exemplary embodiment described in FIG. 5 is almost the same as the exemplary embodiment described in FIG. 1 to FIG. 3. Hereafter, differences between the present exemplary embodiment and the exemplary embodiment of FIG. 1 to FIG. 3 will be described.

Referring to FIG. 5, the adhesive layer 385 on the liquid crystal injection hole formation region 307FP is removed. However, the adhesive layer 385 on the roof layer 360 is remained.

In the present exemplary embodiment, the adhesive layer 385 is removed at the liquid crystal injection hole formation region 307FP, thereby reducing the liquid crystal contamination generated by the contact of the liquid crystal material remaining at the liquid crystal injection hole formation region 307FP and the adhesive layer 385.

Except for the described differences, the contents described in FIG. 1 to FIG. 3 may all be applied to the present exemplary embodiment.

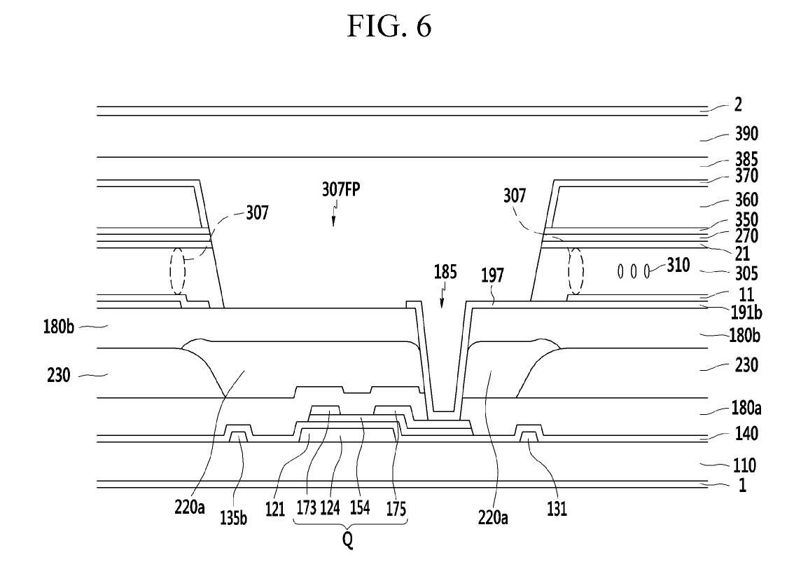

FIG. 6 is a cross-sectional view of a variation of a liquid crystal display according to an exemplary embodiment of FIG. 2.

The exemplary embodiment described in FIG. 6 is almost the same as the exemplary embodiment described in FIG. 1 to FIG. 3. Hereafter, differences between the present exemplary embodiment and the exemplary embodiment of FIG. 1 to FIG. 3 will be described.

Referring to FIG. 6, the liquid crystal material is removed at the liquid crystal injection hole formation region 307FP on which the adhesive layer 385 is disposed. The adhesive layer 385 disposed on the roof layer 360 fills the liquid crystal injection hole formation region 307FP. At this time, the adhesive layer 385 may have a characteristic that its viscosity is changed according to change in temperature. The adhesive layer 385 may have high viscosity at room temperature and have low viscosity at high temperature, for example, more than about 100° C., such that the adhesive layer 385 may reflow into the liquid crystal injection hole formation region 307FP during high temperature heat treatment.

Except for the described differences, the contents described in FIG. 1 to FIG. 3 may all be applied to the present exemplary embodiment.

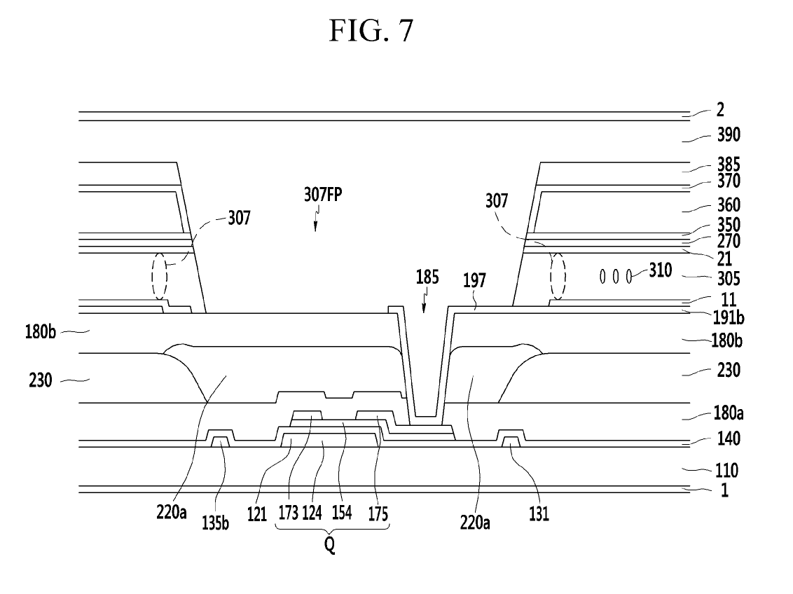

FIG. 7 is a cross-sectional view of a variation of a liquid crystal display according to an exemplary embodiment of FIG. 6.

The exemplary embodiment described in FIG. 7 is almost the same as the exemplary embodiment described in FIG. 1 to FIG. 3. Hereafter, differences between the present exemplary embodiment and the exemplary embodiment of FIG. 1 to FIG. 3 will be described.

Referring to FIG. 7, the liquid crystal material is removed at the liquid crystal injection hole formation region 307FP, and the capping layer 390 is disposed in the liquid crystal injection hole formation region 307FP. The adhesive layer 385 disposed between the capping layer 390 and the roof layer 360 is disposed at a portion corresponding to the roof layer 360, and the adhesive layer 385 on the liquid crystal injection hole formation region 307PF is removed. The capping layer 390 disposed on the adhesive layer 385 may extend to be disposed at the liquid crystal injection hole formation region 307FP. In this case, the capping layer 390 may have a characteristic that viscosity is changed according to change in temperature. The adhesive layer 385 may have high viscosity at room temperature and have low viscosity at high temperature, for example, more than about 100° C., such that the adhesive layer 385 may reflow into the liquid crystal injection hole formation region 307FP during high temperature heat treatment.

Except for the described differences, the contents described in FIG. 6 may all be applied to the present exemplary embodiment.

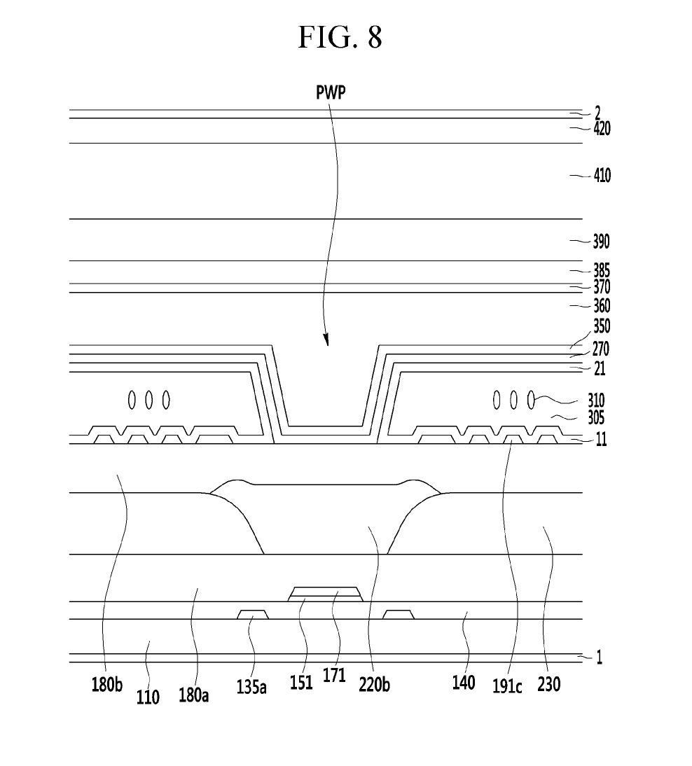

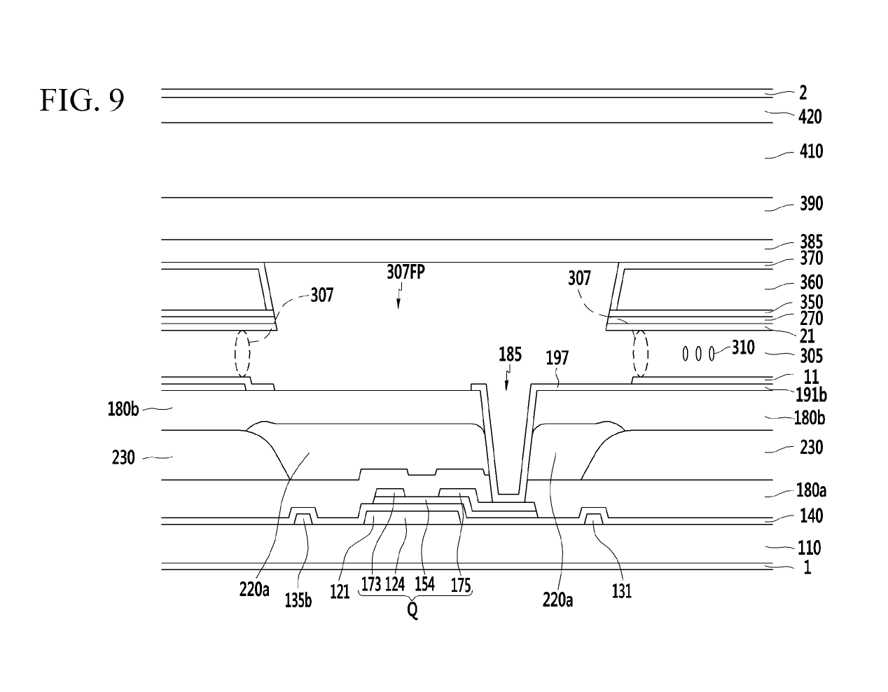

FIG. 8 and FIG. 9 are cross-sectional views of a liquid crystal display according to an exemplary embodiment of the inventive concept.

The exemplary embodiment described in FIG. 8 and FIG. 9 is almost the same as the exemplary embodiment described in FIG. 1 to FIG. 3. Hereafter, differences between the present exemplary embodiment and the exemplary embodiment of FIG. 1 to FIG. 3 will be described.

Referring to FIG. 8 and FIG. 9, an additional capping layer 410 and a protection film 420 are disposed on the capping layer 390. Here, the additional capping layer 410 may be omitted such that the protection film 420 is disposed on the capping layer 390 without intervening the additional capping layer 410.

The additional capping layer 410 includes the same material as the capping layer 390, and the protection film 420 may include the same material as the generally used protection film to prevent external dust or moisture from entering into the liquid crystal display device. The protection film 420 may be formed of a hybrid layer including organic and inorganic materials.

The additional capping layer 410 and the protection film 420 may be formed in the exemplary embodiment described in FIG. 2 to FIG. 7.

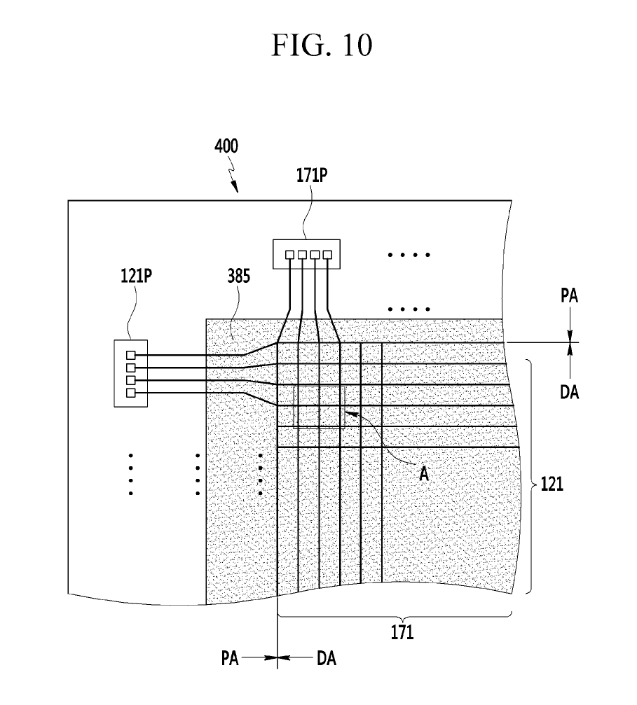

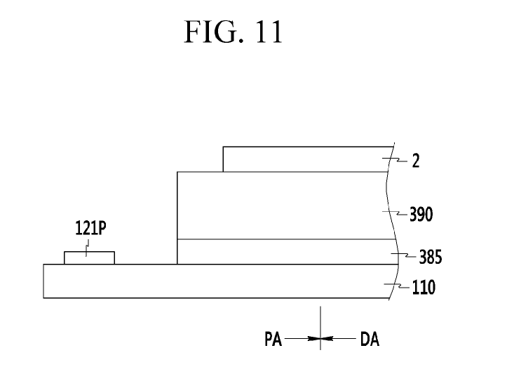

FIG. 10 is a top plan view partially showing a peripheral area and a display area in a liquid crystal display according to an exemplary embodiment of the inventive concept. FIG. 11 is a schematic cross-sectional view of a liquid crystal display according to the exemplary embodiment of FIG. 10. FIG. 11 is omitted the lower polarizer 1 shown in FIG. 2.

Referring to FIG. 10 and FIG. 11, the liquid crystal display according to an exemplary embodiment of the inventive concept may include a liquid crystal panel assembly 400 with a gate driver (not shown) and a data driver (not shown) connected thereto, a gray voltage generator (not shown) connected to the data driver, a light source unit (not shown) irradiating light to the liquid crystal panel assembly 400, a light source driver (not shown) controlling the light source unit, and a signal controller (not shown) controlling them.

The gate driver and/or the data driver may be integrated in the liquid crystal panel assembly 400, or may be formed of a separate integrated circuit chip.

The substrate 110 of the liquid crystal panel assembly 400 includes a display area DA and a non-displaying peripheral area PA. The display area DA is a region where an actual image is displayed, and the non-displaying peripheral region PA is a region where the actual image is not displayed and the gate driver, the data driver, a gate pad portion 121P and a data pad portion 171P including a gate pad, a data pad, or the like are disposed. The gate pad is a wide portion disposed at an end of the gate line 121, and the data pad is a wide portion disposed at an end of the data line 171.

The 2*2 pixel portion of the liquid crystal display described in FIG. 1 to FIG. 3 may correspond to a portion A in FIG. 10.

Again referring to FIG. 11, the upper polarizer 2 is disposed on the capping layer 390, and the upper polarizer 2 exposes a portion of the upper surface of the capping layer 390 by considering an adhesion margin. In the present exemplary embodiment, the upper surface of the capping layer 390 that is exposed between the end of the polarizer 2 and the end of the capping layer 390 may be flat. This structure is generated due to the capping layer 390 that is formed by the lamination method.

The end of the polarizer 2 and the end of the capping layer 390 may be disposed at the peripheral area PA.

The characteristics of the liquid crystal display according to exemplary embodiments of the inventive concept described in FIG. 1 to FIG. 9 may be applied to the exemplary embodiment described in FIG. 10 and FIG. 11. The adhesive layer 385 is formed on the whole area on the substrate 110 in FIG. 10, however the adhesive layer 385 may be removed at the liquid crystal injection hole formation region 307FP in the exemplary embodiment of FIG. 5 and FIG. 7, as described above.

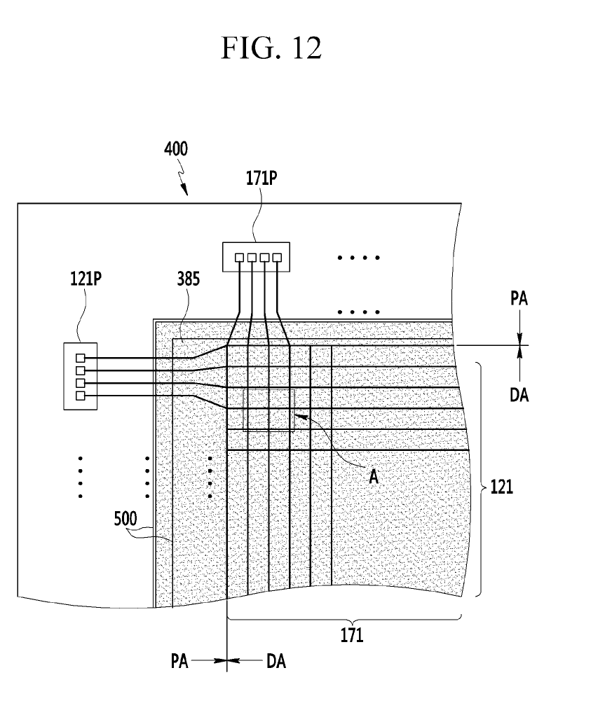

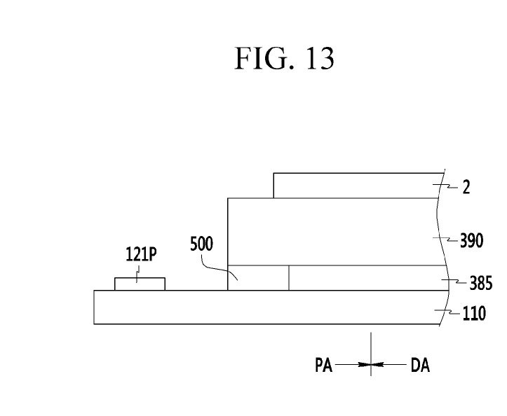

FIG. 12 is a top plan view partially showing a peripheral area and a display area in a liquid crystal display according to an exemplary embodiment of the inventive concept. FIG. 13 is a schematic cross-sectional view of a liquid crystal display according to the exemplary embodiment of FIG. 12.

The exemplary embodiment described in FIG. 12 and FIG. 13 is almost the same as the exemplary embodiment described in FIG. 10 and FIG. 11. Hereafter, differences between the present exemplary embodiment and the exemplary embodiment of FIG. 10 and FIG. 11 will be described.

Referring to FIG. 12 and FIG. 13, a sealing member 500 is disposed at the peripheral area PA. The sealing member 500 may be coated at the peripheral area PA of the substrate 110 before the capping layer 390 is adhered to the liquid crystal panel assembly 400 by the lamination method using the adhesive layer 385. The sealing member 500 may prevent penetration of the external dust or moisture through the peripheral area PA.

Except for the above difference, the contents described in FIG. 10 and FIG. 11 may all be applied to the present exemplary embodiment.

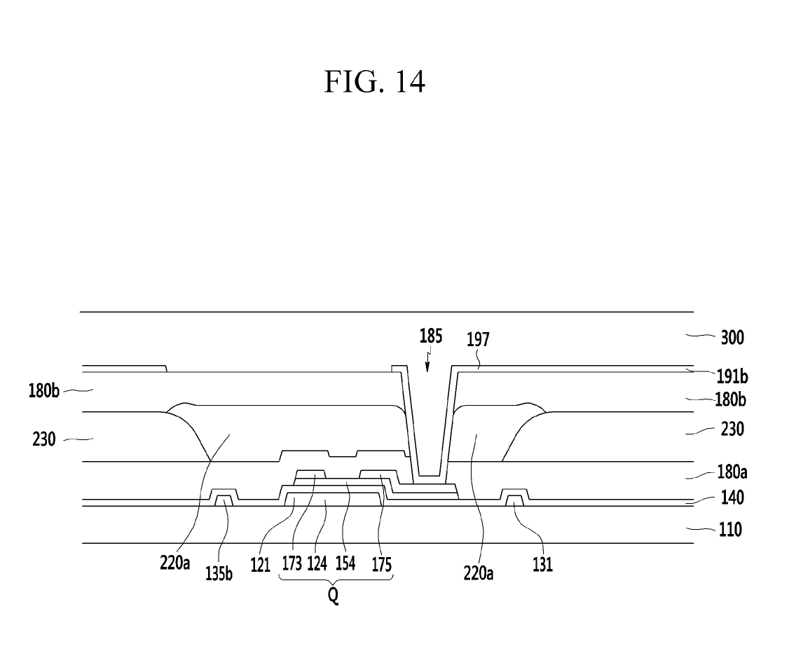

Hereafter, an exemplary embodiment of a method of manufacturing the described liquid crystal display will be described with reference to FIG. 14 to FIG. 30. The following exemplary embodiment may be modified into other methods as an exemplary embodiment of the manufacturing method.

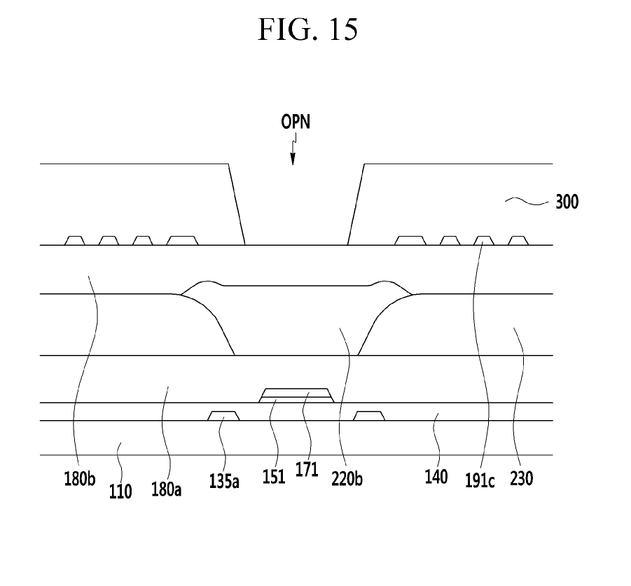

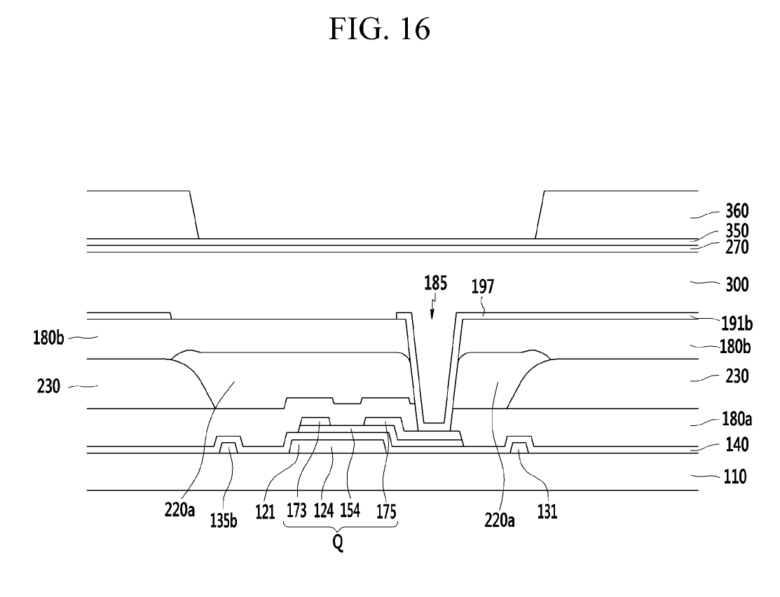

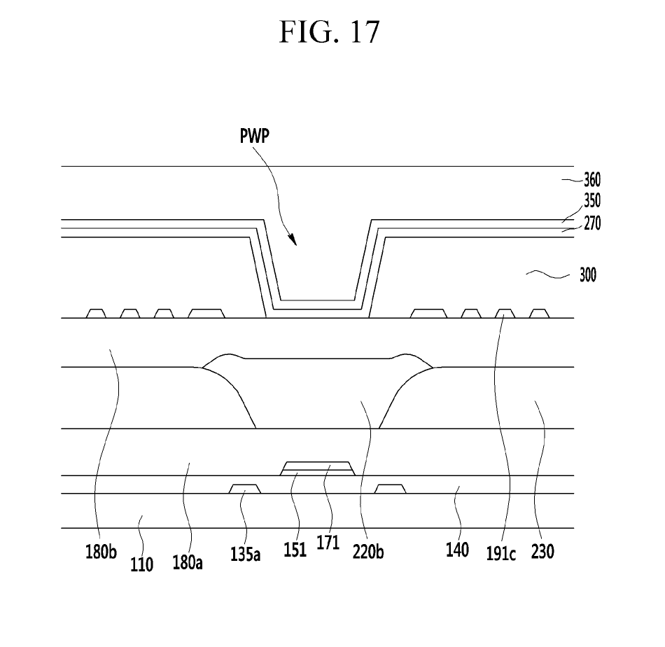

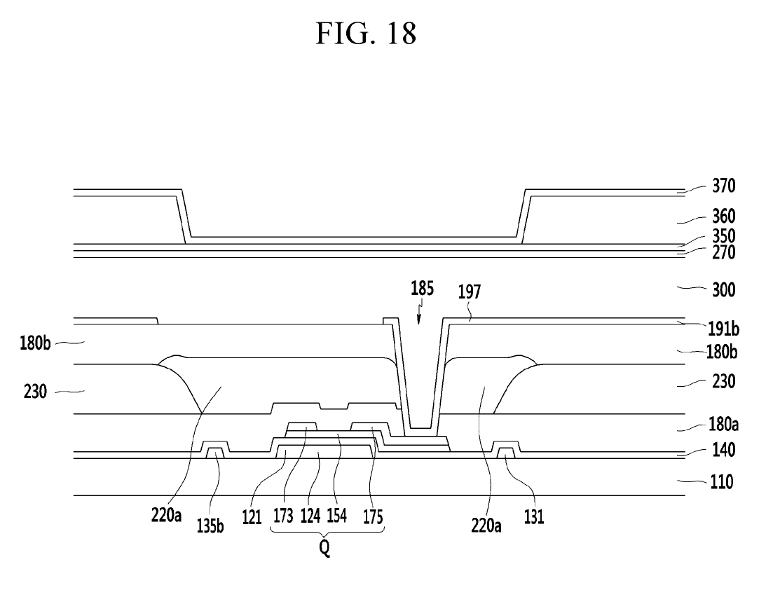

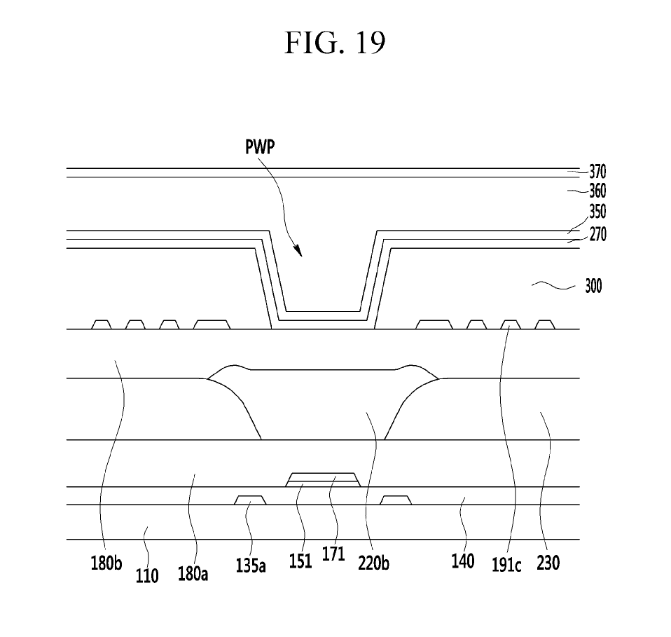

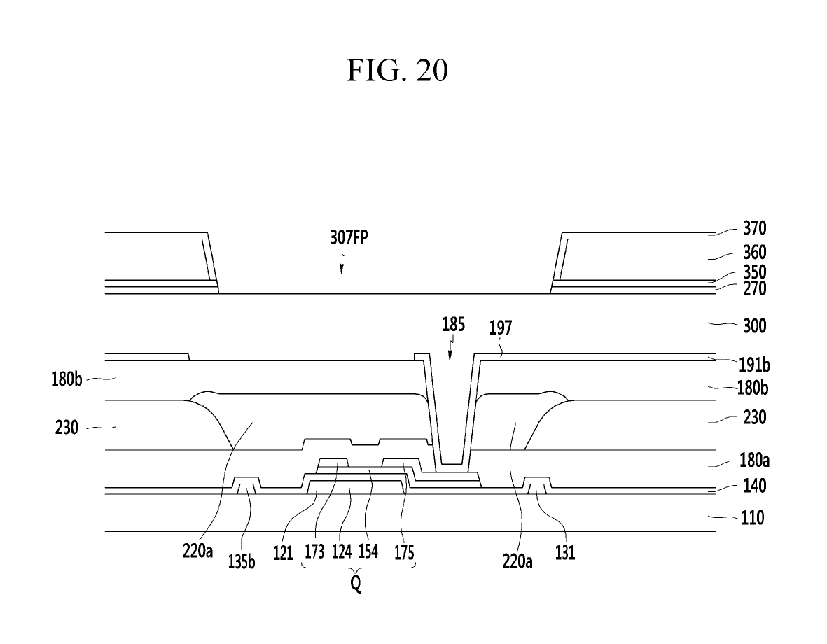

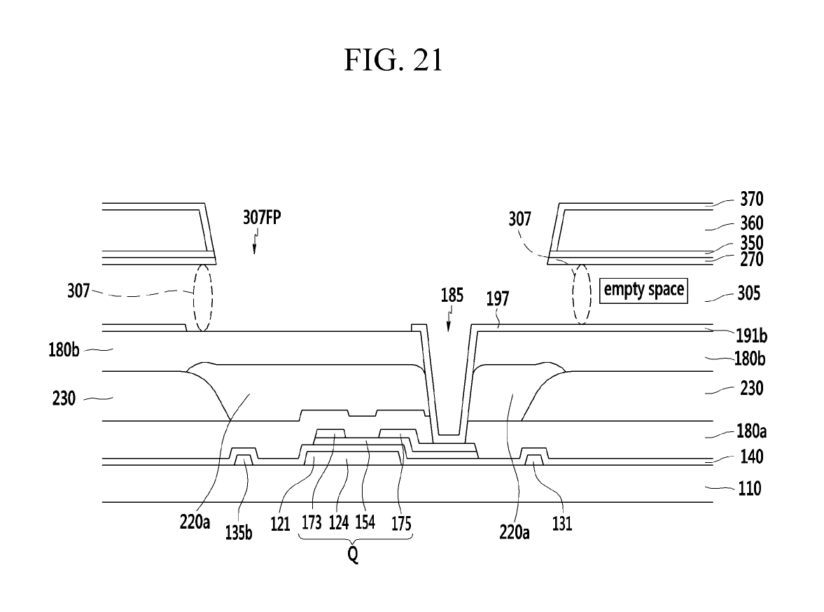

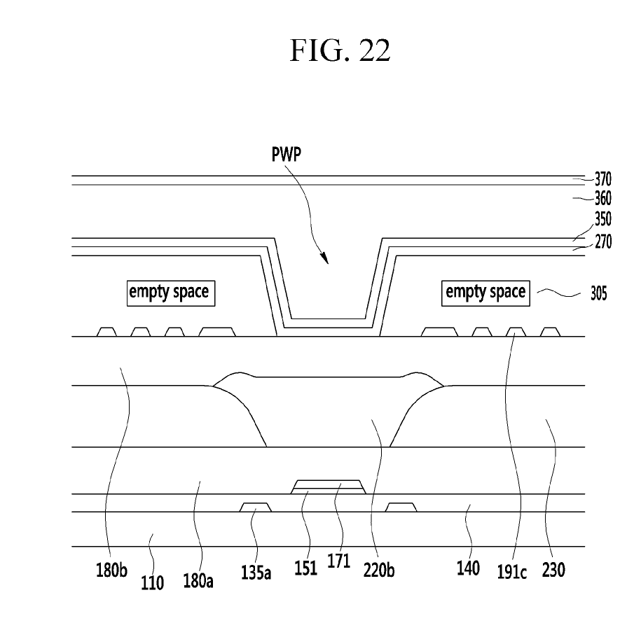

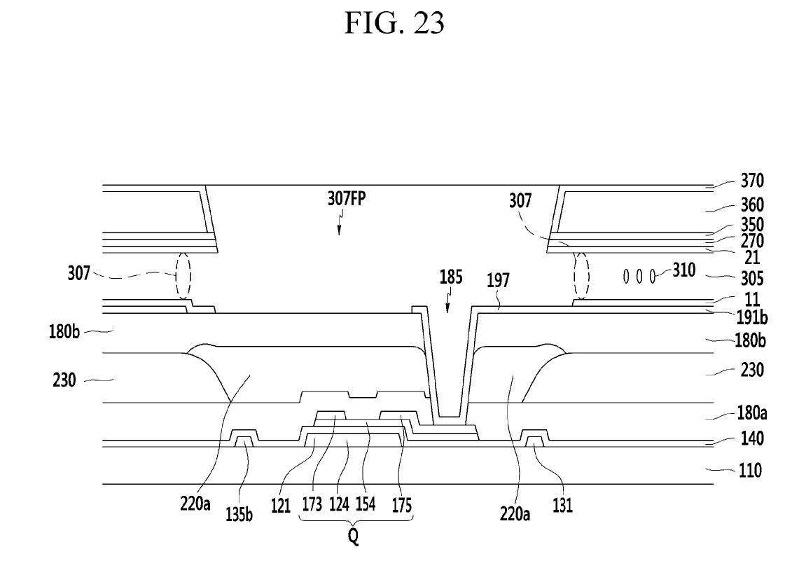

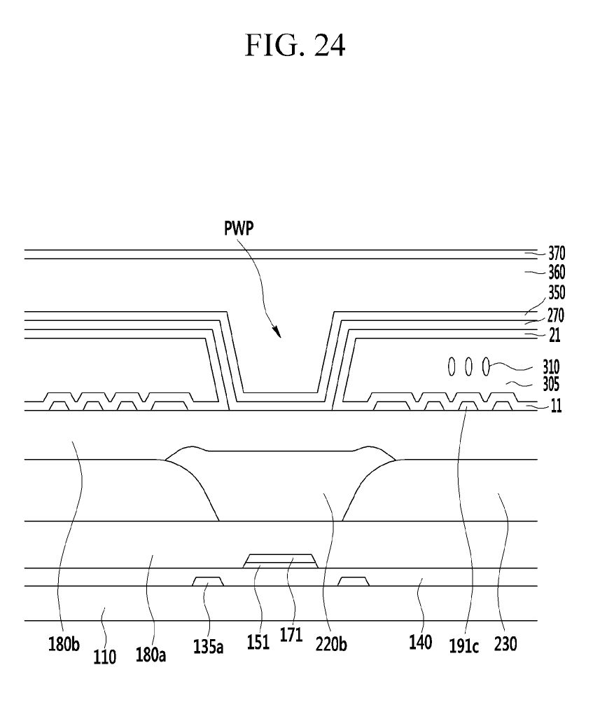

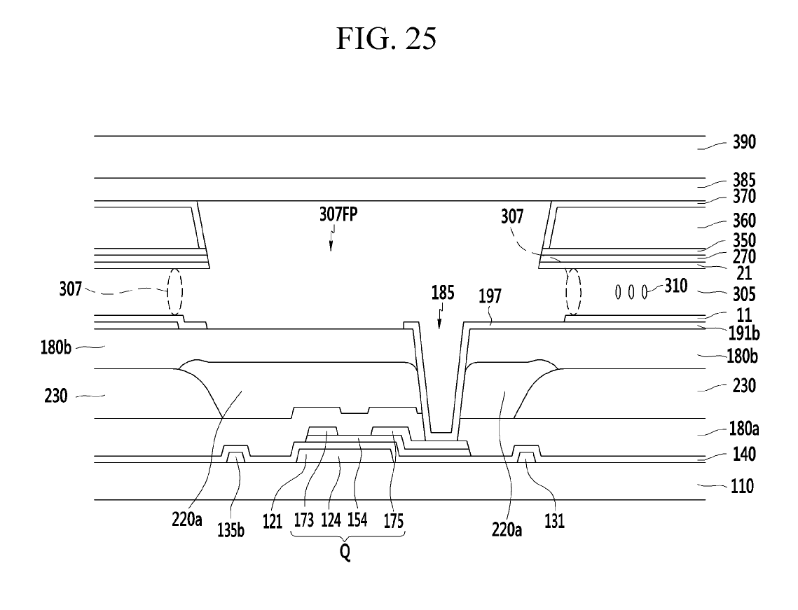

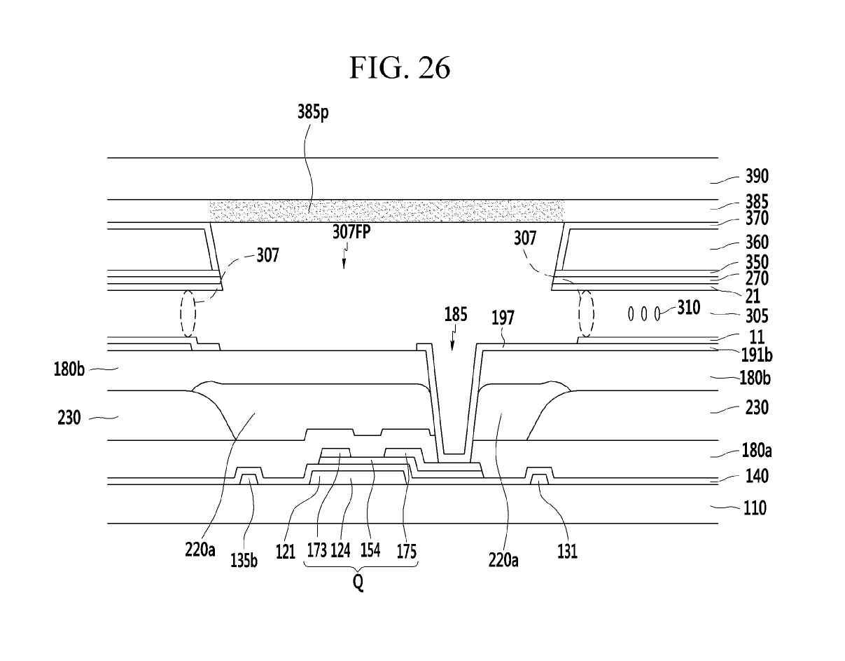

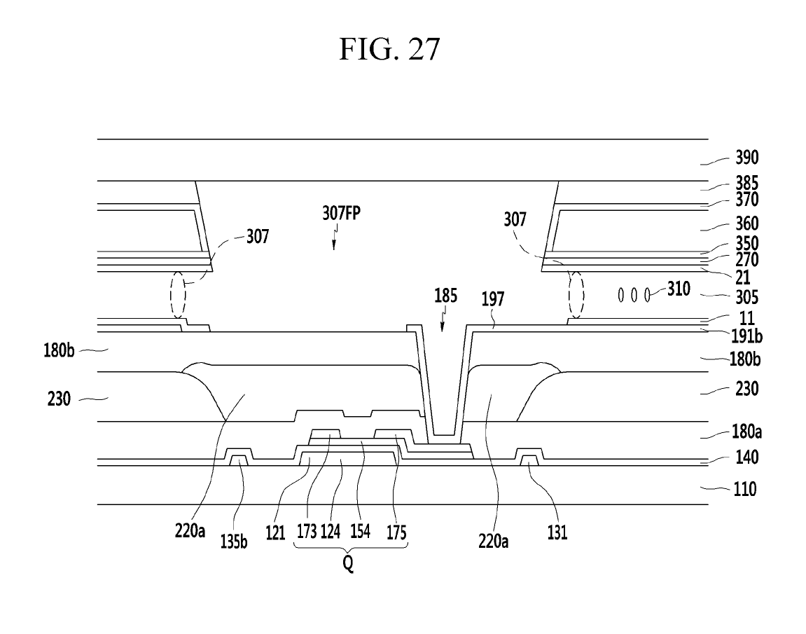

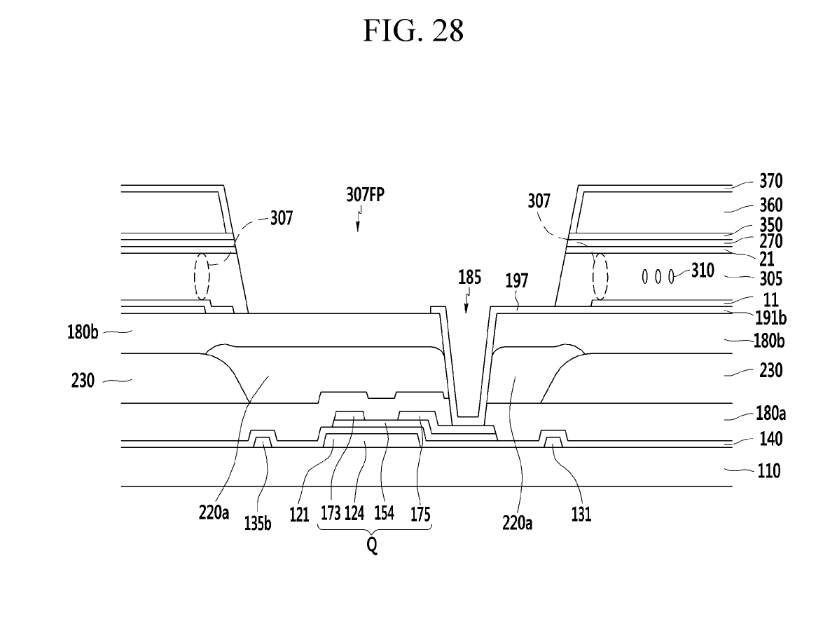

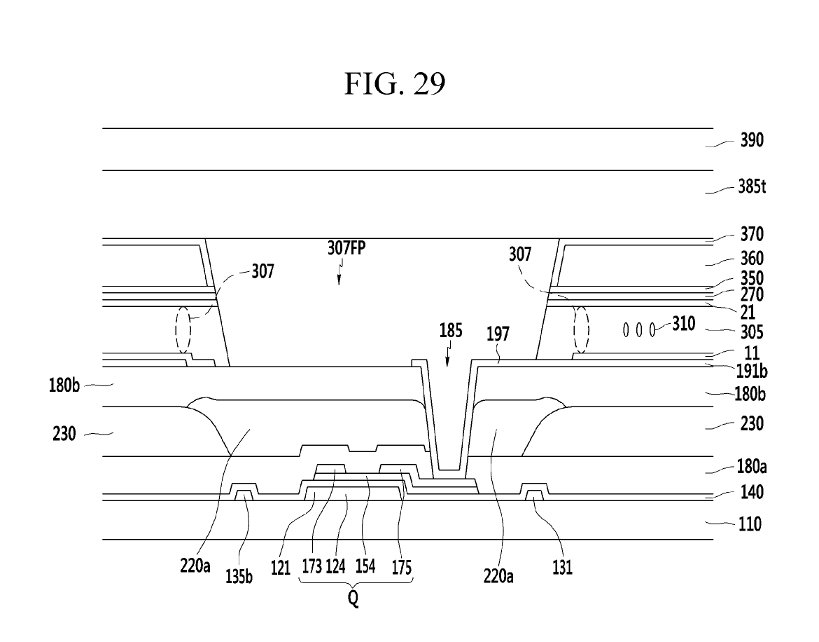

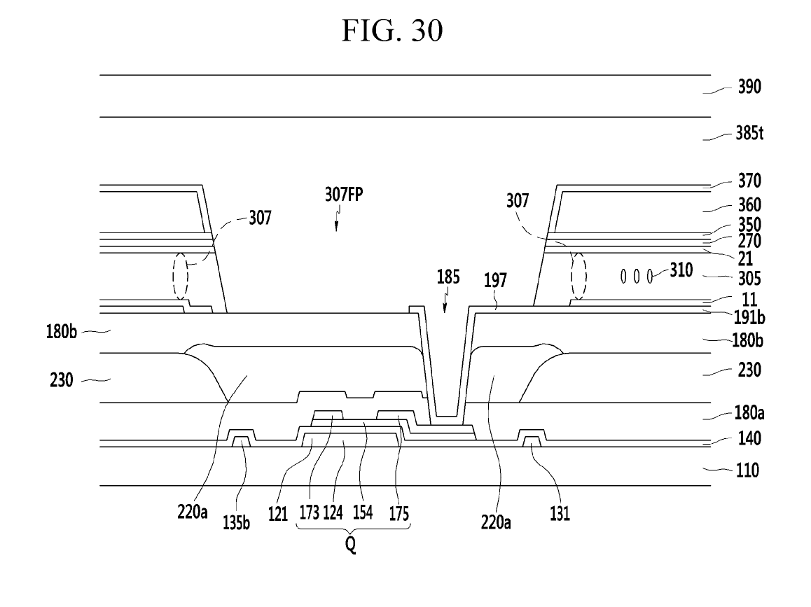

FIG. 14 to FIG. 30 are cross-sectional views showing a manufacturing method of a liquid crystal display according to an exemplary embodiment of the inventive concept. FIG. 14, FIG. 16, FIG. 18, FIG. 20, FIG. 21, FIG. 23, FIG. 25, FIG. 26, FIG. 27, FIG. 28, FIG. 29, and FIG. 30 sequentially show cross-sectional views taken along the line II-II of FIG. 1. FIG. 15, FIG. 17, FIG. 19, FIG. 22, and FIG. 24 are cross-sectional views taken along the line III-III of FIG. 1.

Referring to FIG. 1, FIG. 14, and FIG. 15, in order to form a generally known switching element on a substrate 110, the gate line 121 extending in the horizontal direction is formed, and the gate insulating layer 140 is formed on the gate line 121, the semiconductor layers 151 and 154 are formed on the gate insulating layer 140, and the source electrode 173 and the drain electrode 175 are formed. In this case, the data line 171 connected with the source electrode 173 may be formed to extend in the vertical direction while crossing the gate line 121.

The first interlayer insulating layer 180a is formed on the data conductors including the source electrode 173, the drain electrode 175, and the data line 171, and the exposed portion of the semiconductor layer 154.

The color filter 230 is formed at a position corresponding to the pixel area on the first interlayer insulating layer 180a, and the light blocking members 220a and 220b are formed between the color filters 230. The light blocking member 220 includes the horizontal light blocking member 220a formed in a direction parallel to the gate line 121, and the vertical light blocking member 220b formed in a direction parallel to the data line 171.

The second interlayer insulating layer 180b covering the color filter 230 and the light blocking member 220 is formed on the color filter 230 and the light blocking member 220, and the second interlayer insulating layer 180b is formed to have the contact hole 185 electrically and physically connecting the pixel electrode 191 and the drain electrode 175.

Next, the pixel electrode 191 including the horizontal stem 191a, the vertical stem 191b and the minute branches 191c is formed on the second interlayer insulating layer 180b, and a sacrificial layer 300 is formed on the pixel electrode 191. As shown in FIG. 15, an opening OPN is formed in the sacrificial layer 300 along a direction in parallel with the data line 171. In a subsequent process, the common electrode 270, the lower insulating layer 350, the roof layer 360, and the upper insulating layer 370 are filled in the open portion OPN to form the partition wall formation portion PWP.

Referring to FIG. 1, FIG. 16, and FIG. 17, the common electrode 270, the lower insulating layer 350, and the roof layer 360 are sequentially formed on the sacrificial layer 300. The roof layer 360 may be removed at the region corresponding to the light blocking member 220 disposed between pixel areas adjacent in the vertical direction by an exposure and development process. The roof layer 360 exposes the lower insulating layer 350 in the region corresponding to the light blocking member 220. In this case, the common electrode 270, the lower insulating layer 350, and the roof layer 360 fill the open portion OPN of the vertical light blocking member 220b thereby forming the partition forming portion PWP.

Referring to FIG. 1, FIG. 18, and FIG. 19, the upper insulating layer 370 is formed in such a way so as to cover the roof layer 360 and the exposed lower insulating layer 350.

Referring to FIG. 20, the upper insulating layer 370, the lower insulating layer 350, and the common electrode 270 are dry-etched to partially remove the upper insulating layer 370, the lower insulating layer 350, and the common electrode 270, thereby forming the liquid crystal injection hole formation region 307FP. In this case, the upper insulating layer 370 may have a structure that covers a side surface of the roof layer 360, however, it is not limited thereto. The upper insulating layer 370 covering the side surface of the roof layer 360 may be removed so that the side surface of the roof layer 360 may be externally exposed.

Referring to FIG. 21 and FIG. 22, the sacrificial layer 300 is removed by an oxygen (O2) ashing process or a wet-etching method through the liquid crystal injection hole formation region 307FP. At this time, the microcavity 305 having the liquid crystal injection hole 307 is formed. The microcavities 305 are in a state of an empty space according to the removal of the sacrificial layer 300.

Referring to FIG. 23 and FIG. 24, the alignment layers 11 and 21 are formed on the pixel electrode 191 and the common electrode 270 by injecting an aligning material through the liquid crystal injection hole 307. In detail, a baking process is performed after injecting the aligning material containing a solid content and a solvent through the liquid crystal injection hole 307.

Next, the liquid crystal material including the liquid crystal molecules 310 is injected into the microcavities 305 through the liquid crystal injection hole 307 by using an inkjet method and the like. At this time, the liquid crystal material that is injected through the liquid crystal injection hole formation region 307FP is injected to the microcavity 305 and some of the liquid crystal material may remain in the liquid crystal injection hole formation region 307FP. The amount of the liquid crystal material may be controlled to fill the liquid crystal injection hole formation region 307FP by the liquid crystal material.

Referring to FIG. 25, the capping layer 390 is adhered to the upper insulating layer 370 by using the lamination method. When omitting the upper insulating layer 370, the capping layer 390 may be adhered to the roof layer 360. The adhesive layer 385 is disposed between the capping layer 390 and the upper insulating layer 370. The adhesive layer 385 may be formed in the whole area at the adhesion surface of the capping layer 390. Next, if the polarizers 1 and 2 are formed on the capping layer 390 and under the substrate 110, the liquid crystal display shown in FIG. 2 may be formed.

Referring to FIG. 26, before adhering the capping layer 390 on the upper insulating layer 370, the heat treatment is applied or UV is irradiated to a portion of the adhesive layer 385 formed at the adhesion surface of the capping layer 390 to form the hardened adhesion region 385p. Next, the capping layer 390 may be formed on the upper insulating layer 370 for the hardened adhesion region 385p to correspond to the liquid crystal injection hole formation region 307FP. Next, the polarizers 1 and 2 are formed on the capping layer 390 and under the substrate 110, thereby forming the liquid crystal display as shown in FIG. 4.

Referring to FIG. 27, differently from FIG. 25, the adhesive layer 385 formed at the adhesion surface of the capping layer 390 may be removed. Next, the capping layer 390 may be formed on the upper insulating layer 370 for the remained adhesive layer 385 so as to correspond to the upper surface of the roof layer 360. In this case, the adhesive layer 385 is removed in the liquid crystal injection hole formation region 307FP, and the capping layer 390 covers the liquid crystal injection hole formation region 307FP. Next, the polarizers 1 and 2 are formed on the capping layer 390 and under the substrate 110, thereby forming the liquid crystal display shown in FIG. 5.

Referring to FIG. 28 to FIG. 30, differently from the description of FIG. 25 to FIG. 27, the liquid crystal material is removed in the liquid crystal injection hole formation region 307FP.

Referring to FIG. 28, the liquid crystal material in the liquid crystal injection hole formation region 307FP is removed by using a cleaning method after the process of FIG. 23 and FIG. 24.

Referring to FIG. 29, an adhesive layer 385t having the characteristic that the viscosity is changed according to the temperature is formed at the adhesion surface of the capping layer 390, and the capping layer 390 is adhered on the upper insulating layer 370 by using the lamination method. Here, the capping layer 390 may be adhered to the upper insulating layer 370 by the adhesive layer 385t. At this time, the adhesive layer 385t has high viscosity o at room temperature (about 15° C. to 25° C.) thereby maintaining the shape of the adhesive layer 385t. Accordingly, as shown in FIG. 29, the liquid crystal injection hole formation region 307FP enclosed by the adhesive layer 385t and the roof layer 360 is the empty space.

Referring to FIG. 30, the high temperature heat treatment of more than about 100° C. is used to decrease the viscosity of the adhesive layer 385t such that the adhesive layer 385t reflows into the liquid crystal injection hole formation region 307FP.

Next, the polarizers 1 and 2 are formed on the capping layer 390 and under the substrate 110 thereby forming the liquid crystal display as shown in FIG. 6.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the appended claims.

What is claimed is:

1. A liquid crystal display comprising:
a substrate;
a thin film transistor disposed on the substrate;
a pixel electrode connected to the thin film transistor;
a roof layer facing the pixel electrode;
an adhesive layer disposed on the roof layer; and
a capping layer disposed on the adhesive layer,
wherein a plurality of microcavities are formed between the pixel electrode and the roof layer, and each microcavity forms a liquid crystal layer including a liquid crystal material.

2. The liquid crystal display of claim 1, wherein a liquid crystal injection hole formation region is formed between a plurality of microcavities, and the liquid crystal material is disposed at the liquid crystal injection hole formation region.

3. The liquid crystal display of claim 2, wherein a lower portion of the capping layer corresponding to the liquid crystal injection hole formation region is substantially flat.

4. The liquid crystal display of claim 3, wherein the adhesive layer is disposed on the roof layer and is removed in the liquid crystal injection hole formation region.

5. The liquid crystal display of claim 4, further comprising a sealing member,
wherein the sealing member surrounds a display area and is disposed at the peripheral area in which image in not displayed.

6. The liquid crystal display of claim 1, wherein
a liquid crystal injection hole formation region is formed between the plurality of microcavities, and the adhesive layer is disposed at the liquid crystal injection hole formation region.

7. The liquid crystal display of claim 6, wherein the adhesive layer has a characteristic that viscosity is changed according to temperature.

8. The liquid crystal display of claim 7, further comprising a sealing member,
wherein the sealing member surrounds a display area and is disposed at the peripheral area in which image in not displayed.

9. The liquid crystal display of claim 1, wherein
the liquid crystal injection hole formation region is formed between a plurality of microcavities, the capping layer is disposed at the liquid crystal injection hole formation region, and
the adhesive layer is disposed on the roof layer and is removed at the liquid crystal injection hole formation region.

10. The liquid crystal display of claim 1, further comprising a polarizer disposed on the capping layer, and
wherein an upper surface of the capping layer that is exposed between an end of the polarizer and an end of the capping layer is flat.

11. The liquid crystal display of claim 10, wherein
the end of the polarizer and the end of the capping layer are disposed at the peripheral area of the substrate.

12. The liquid crystal display of claim 1, further comprising
a protection film disposed on the capping layer.

13. The liquid crystal display of claim 1, wherein
the liquid crystal injection hole formation region is formed between a plurality of microcavities, and the adhesive layer includes a hardened adhesion region disposed at a portion corresponding to the liquid crystal injection hole formation region.

14. A method of manufacturing a liquid crystal display, comprising:
forming a thin film transistor on a substrate;
forming a pixel electrode to be connected to one terminal of the thin film transistor;
forming a sacrificial layer on the pixel electrode;
forming a roof layer on the sacrificial layer;
removing the sacrificial layer to form a plurality of microcavities;
injecting a liquid crystal material into the microcavities; and
attaching a capping layer on the roof layer.

15. The method of claim 14, wherein the capping layer has an adhesive layer on at least one surface and attaching a capping layer on the roof layer is performed by the adhesive.

16. The method of claim 15, further comprising
forming a liquid crystal injection hole formation region between a plurality of microcavities, and
the injecting of the liquid crystal material includes forming a liquid crystal material at the liquid crystal injection hole formation region.

17. The method of claim 16, wherein:
the capping layer includes a first portion corresponding to the roof layer and a second portion corresponding to the liquid crystal injection hole formation region; and
the adhesive layer is formed at the first portion and is removed at the second portion in the forming of the adhesive layer.

18. The method of claim 17, further comprising forming a sealing member at the peripheral area in which image in not displayed,
wherein the sealing member surrounds a display area.

19. The method of claim 15, further comprising
forming a liquid crystal injection hole formation region between a plurality of microcavities, and
removing the liquid crystal material on the liquid crystal injection hole formation region.

20. The method of claim 19, wherein
the adhesive layer has a characteristic that viscosity is changed according to temperature, and
the forming of the adhesive layer includes
heat-treating the adhesive layer to reflow the adhesive layer into the liquid crystal injection hole formation region.

21. The method of claim 20, further comprising forming a sealing member at the peripheral area in which image in not displayed,
wherein the sealing member surrounds a display area.

22. The method of claim 19, wherein
the forming of the capping layer includes
heat-treating the capping layer to reflow the capping layer into the liquid crystal injection hole formation region.

23. The method of claim 14, further comprising
forming a polarizer on the capping layer, and
an upper surface of the capping layer exposed between an end of the polarizer and an end of the capping layer is flat.

24. The method of claim 23, wherein
the end of the polarizer and the end of the capping layer are formed to be disposed in the peripheral area of the substrate.

25. The method of claim 14, further comprising
forming a protection film on the capping layer.

26. The method of claim 14, further comprising:
forming a liquid crystal injection hole formation region between a plurality of microcavities;
forming an adhesive layer between the roof layer and the capping layer; and
heat-treating or irradiating UV to a portion of the adhesive layer corresponding to the liquid crystal injection hole formation region to form a hardened adhesion region.
